(19) United States
(12) Patent Application Publication
(10) Pub. No.: US 2008/0087882 A1
(43) Pub. Date: Apr. 17, 2008

(54) PROCESS FOR MAKING CONTAINED LAYERS AND DEVICES MADE WITH SAME

(76) Inventors: Daniel David Lecloux, Wilmington, DE (US); Eric Maurice Smith, Hockessin, DE (US); Gary A. Johansson, Hockessin, DE (US)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(21) Appl. No.: 11/758,269

(22) Filed: Jun. 5, 2007

Related U.S. Application Data
(60) Provisional application No. 60/810,939, filed on Jun. 5, 2006.

(51) Int. Cl. H01L 51/56; H01L 51/52

(52) U.S. Cl. 257/40; 438/99; 438/22; 438/759; 438/763; 257/E51.018; 257/E21.483; 257/E21.461

(57) ABSTRACT

There is provided a process for forming a contained second layer over a first layer, including the steps: forming the first layer having a first surface energy; forming an intermediate layer over and in direct contact with the first layer, said intermediate layer having a second surface energy which is lower than the first surface energy; removing selected portions of the intermediate layer to form a pattern comprising uncovered areas of the first layer and covered areas of the first layer; and forming a contained second layer over the uncovered areas of the first layer. There is also provided an organic electronic device made by the process.

### BACKGROUND INFORMATION

1. Field of the Disclosure

This disclosure relates in general to a process for making an electronic device. It further relates to the device made by the process.

2. Description of the Related Art

Electronic devices utilizing organic active materials are present in many different kinds of electronic equipment. In such devices, an organic active layer is sandwiched between two electrodes.

One type of electronic device is an organic light emitting diode (OLED). OLEDs are promising for display applications due to their high power-conversion efficiency and low processing costs. Such displays are especially promising for battery-powered, portable electronic devices, including cell-phones, personal digital assistants, handheld personal computers, and DVD players. These applications call for displays with high information content, full color, and fast video rate response time in addition to low power consumption.

Current research in the production of full-color OLEDs is directed toward the development of cost effective, high throughput processes for producing color pixels. For the manufacture of monochromatic displays by liquid processing, spin-coating processes have been widely adopted (see, e.g., David Braun and Alan J. Heeger, Appl. Phys. Letters 58, 1982 (1991)). However, manufacture of full-color displays requires certain modifications to procedures used in manufacture of monochromatic displays. For example, to make a display with full-color images, each display pixel is divided into three subpixels, each emitting one of the three primary display colors, red, green, and blue. This division of full-color pixels into three subpixels has resulted in a need to modify current processes to prevent the spreading of the liquid colored materials (i.e., inks) and color mixing.

Several methods for providing ink containment are described in the literature. These are based on containment structures, surface tension discontinuities, and combinations of both. Containment structures are geometric obstacles to spreading: pixel wells, banks, etc. In order to be effective these structures must be large, comparable to the wet thickness of the deposited materials. When the emissive ink is printed into these structures it wets onto the structure surface, so thickness uniformity is reduced near the structure. Therefore the structure must be moved outside the emissive “pixel” region so the non-uniformities are not visible in operation. Due to limited space on the display (especially high-resolution displays) this reduces the available emissive area of the pixel. Practical containment structures generally have a negative impact on quality when depositing continuous layers of the charge injection and transport layers. Consequently, all the layers must be printed.

In addition, surface tension discontinuities are obtained when there are either printed or vapor deposited regions of low surface tension materials. These low surface tension materials generally must be applied before printing or coating the first organic active layer in the pixel area. Generally the use of these treatments impacts the quality when coating continuous non-emissive layers, so all the layers must be printed.

An example of a combination of two ink containment techniques is CF₄-plasma treatment of photoresist bank structures (pixel wells, channels). Generally, all of the active layers must be printed in the pixel areas.

All these containment methods have the drawback of precluding continuous coating. Continuous coating of one or more layers is desirable as it can result in higher yields and lower equipment cost. There exists, therefore, a need for improved processes for forming electronic devices.

### SUMMARY

There is provided a process for forming a contained second layer over a first layer, said process comprising:
forming the first layer having a first surface energy;
forming an intermediate layer over and in direct contact with the first layer, said intermediate layer having a second surface energy which is lower than the first surface energy;
removing selected portions of the intermediate layer to form a pattern comprising uncovered areas of the first layer and covered areas of the first layer; and
forming a contained second layer over the uncovered areas of the first layer.

There is provided a process for making an organic electronic device comprising a first organic active layer and a second organic active layer positioned over an electrode, said process comprising:
forming the first organic active layer having a first surface energy over the electrode;
forming an intermediate layer over and in direct contact with the first layer, said intermediate layer having a second surface energy which is lower than the first surface energy;
removing selected portions of the intermediate layer to form a pattern comprising uncovered areas of the first layer and covered areas of the first layer; and
forming a contained second layer over the uncovered areas of the first layer.

There is also provided an organic electronic device comprising a first organic active layer and a second organic active layer positioned over an electrode, and further comprising a patterned intermediate layer between the first organic active layer and the second organic active layer.

The foregoing general description and the following detailed description are exemplary and explanatory only and are not restrictive of the invention, as defined in the appended claims.

### BRIEF DESCRIPTION OF THE DRAWINGS

Embodiments are illustrated in the accompanying figures to improve understanding of concepts as presented herein.

FIG. 1 includes a diagram illustrating contact angle.

FIG. 2 includes an illustration of an organic electronic device.

Skilled artisans appreciate that objects in the figures are illustrated for simplicity and clarity and have not necessarily been drawn to scale. For example, the dimensions of some of the objects in the figures may be exaggerated relative to other objects to help to improve understanding of embodiments.

### DETAILED DESCRIPTION

There is provided a process for forming a contained second layer over a first layer, said process comprising:
forming the first layer having a first surface energy;
forming an intermediate layer over and in direct contact with the first layer, said intermediate layer having a second surface energy which is lower than the first surface energy;
removing selected portions of the intermediate layer to form a pattern comprising uncovered areas of the first layer and covered areas of the first layer; and
forming a contained second layer over the uncovered areas of the first layer.

Many aspects and embodiments have been described above and are merely exemplary and not limiting. After reading this specification, skilled artisans appreciate that other aspects and embodiments are possible without departing from the scope of the invention.

Other features and benefits of any one or more of the embodiments will be apparent from the following detailed description, and from the claims. The detailed description first addresses Definitions and Clarification of Terms followed by the Materials, the Process, the Organic Electronic Device, and finally Examples.

### 1. Definitions and Clarification of Terms

Before addressing details of embodiments described below, some terms are defined or clarified.

The term “active” when referring to a layer or material, is intended to mean a layer or material that exhibits electronic or electro-radiative properties. In an electronic device, an active material electronically facilitates the operation of the device. Examples of active materials include, but are not limited to, materials which conduct, inject, transport, or block a charge, where the charge can be either an electron or a hole, and materials which emit radiation or exhibit a change in concentration of electron-hole pairs when receiving radiation. Examples of inactive materials include, but are not limited to, planarization materials, insulating materials, and environmental barrier materials.

The term “contained” when referring to a layer, is intended to mean that the layer does not spread significantly beyond the area where it is deposited. The layer can be contained by surface energy effects or a combination of surface energy effects and physical barrier structures.

The term “electrode” is intended to mean a member or structure configured to transport carriers within an electronic component. For example, an electrode may be an anode, a cathode, a capacitor electrode, a gate electrode, etc. An electrode may include a part of a transistor, a capacitor, a resistor, an inductor, a diode, an electronic component, a power supply, or any combination thereof.

The term “organic electronic device” is intended to mean a device including one or more organic semiconductor layers or materials. An organic electronic device includes, but is not limited to: (1) a device that converts electrical energy into radiation (e.g., a light-emitting diode, light emitting diode display, diode laser, or lighting panel), (2) a device that detects a signal using an electronic process (e.g., a photodetector, a photoconductive cell, a photoresistor, a photoswitch, a phototransistor, a phototube, an infrared (“IR”) detector, or a biosensors), (3) a device that converts radiation into electrical energy (e.g., a photovoltaic device or solar cell), (4) a device that includes one or more electronic components that include one or more organic semiconductor layers (e.g., a transistor or diode), or any combination of devices in items (1) through (4).

The term “fluorinated” when referring to an organic compound, is intended to mean that one or more of the hydrogen atoms in the compound have been replaced by fluorine. The term encompasses partially and fully fluorinated materials.

The term “surface energy” is the energy required to create a unit area of a surface from a material. A characteristic of surface energy is that liquid materials with a given surface energy will not wet surfaces with a lower surface energy.

The term “layer” is used interchangeably with the term “film” and refers to a coating covering a desired area. The term is not limited by size. The area can be as large as an entire device or as small as a specific functional area such as the actual visual display, or as small as a single sub-pixel. Layers and films can be formed by any conventional deposition technique, including vapor deposition, liquid deposition (continuous and discontinuous techniques), and thermal transfer.

The term “liquid composition” is intended to mean a liquid medium in which a material is dissolved to form a solution, a liquid medium in which a material is dispersed to form a dispersion, or a liquid medium in which a material is suspended to form a suspension or an emulsion. “Liquid medium” is intended to mean a material that is liquid without the addition of a solvent or carrier fluid, i.e., a material at a temperature above its solidification temperature.

The term “liquid containment structure” is intended to mean a structure within or on a workpiece, wherein such one or more structures, by itself or collectively, serve a principal function of constraining or guiding a liquid within an area or region as it flows over the workpiece. A liquid containment structure can include cathode separators or a well structure.

The term “liquid medium” is intended to mean a liquid material, including a pure liquid, a combination of liquids, a solution, a dispersion, a suspension, and an emulsion. Liquid medium is used regardless whether one or more solvents are present.

As used herein, the term “over” does not necessarily mean that a layer, member, or structure is immediately next to or in contact with another layer, member, or structure. There may be additional, intervening layers, members or structures.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, use of “a” or “an” are employed to describe elements and components described herein. This is done merely for convenience and to give a general sense of the scope of the invention. This description should be read to include one or at least one and the singular also includes the plural unless it is obvious that it is meant otherwise.

Group numbers corresponding to columns within the Periodic Table of the elements use the “New Notation” convention as seen in the CRC Handbook of Chemistry and Physics, 81^{st} Edition (2000-2001).

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the present invention, suitable methods and materials are described below. All publications, patent applications, patents, and other references mentioned herein are incorporated by reference in their entirety, unless a particular passage is cited. In case of conflict, the present specification, including definitions, will control. In addition, the materials, methods, and examples are illustrative only and not intended to be limiting.

To the extent not described herein, many details regarding specific materials, processing acts, and circuits are conventional and may be found in textbooks and other sources within the organic light-emitting diode display, photodetector, photovoltaic, and semiconductive member arts.

### 2. Materials

The materials for the first and second layers are determined in large part by the intended end use of the article in which they are contained. The material of the intermediate layer is selected to provide containment for the second layer. This is done by adjusting the surface energy of the intermediate layer to be less than the surface energy of the first layer.

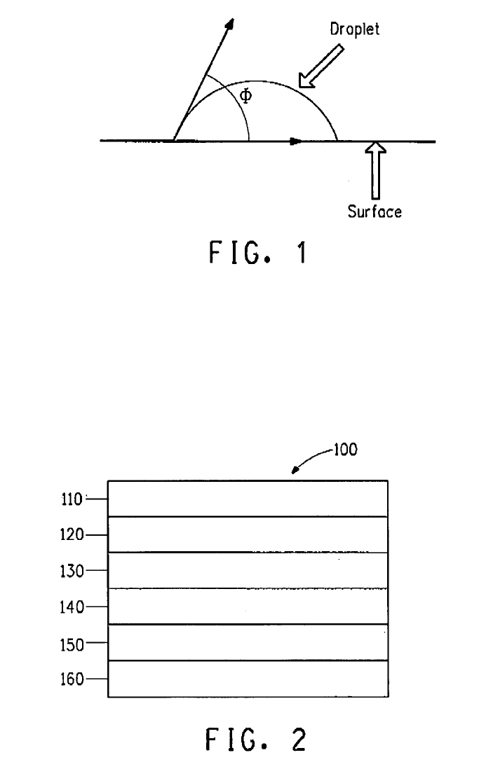

One way to determine the relative surface energies, is to compare the contact angle of a given liquid on a layer. As used herein, the term “contact angle” is intended to mean the angle φ shown in FIG. 1. For a droplet of liquid medium, angle φ is defined by the intersection of the plane of the surface and a line from the outer edge of the droplet to the surface. Furthermore, angle φ is measured after the droplet has reached an equilibrium position on the surface after being applied, i.e. “static contact angle”. A variety of manufacturers make equipment capable of measuring contact angles.

In some embodiments, the first surface energy is high enough so that it is wettable by many conventional solvents. In some embodiments, the first layer is wettable by phenylhexane with a contact angle no greater than 40°.

The intermediate layer has a second surface energy which is lower than the first surface energy. In some embodiments, the intermediate layer is not wettable by phenylhexane, with a contact angle of at least 70°.

In one embodiment, the intermediate layer comprises a fluorinated material. In one embodiment, the intermediate layer comprises a material having perfluoroalkylether groups. In one embodiment, the fluoroalkyl groups have from 2-20 carbon atoms. In one embodiment, the intermediate layer comprises a fluorinated alkylene backbone with pendant perfluoroalkylether side chains.

In one embodiment, the intermediate layer comprises a fluorinated acid. In one embodiment, the fluorinated acid is an oligomer. In one embodiment, the oligomer has a fluorinated olefin backbone, with pendant fluorinated ether sulfonate, fluorinated ester sulfonate, or fluorinated ether sulfonimide groups. In one embodiment, the fluorinated acid is an oligomer of 1,1-difluoroethylene and 2-(1,1-difluoro-2-(trifluoromethyl)allyloxy)-1,1,2,2-tetrafluoroethanesulfonic acid. In one embodiment, the fluorinated acid is an oligomer of ethylene and 2-(2-(1,2,2-trifluorovinyloxy)-1,1,2,3,3,3-hexafluoropropoxy)-1,1,2,2-tetrafluoroethanesulfonic acid. These oligomers can be made as the corresponding sulfonyl fluoride oligomer and then can be converted to the sulfonic acid form. In one embodiment, the fluorinated acid polymer is an oligomer of a fluorinated and partially sulfonated poly(arylene ether sulfone).

### 3. Process

In the process provided herein, a first layer is formed, an intermediate layer is formed over the first layer, selected portions of the intermediate layer are removed to form a patterned intermediate layer with uncovered areas of the first layer, and a contained second layer is formed over the uncovered areas of the first.

In one embodiment, the first layer is a substrate. The substrate can be inorganic or organic. Examples of substrates include, but are not limited to glasses, ceramics, and polymeric films, such as polyester and polyimide films.

In one embodiment, the first layer is an electrode. The electrode can be unpatterned, or patterned. In one embodiment, the electrode is patterned in parallel lines. The electrode can be on a substrate.

In one embodiment, the first layer is deposited on a substrate. The first layer can be patterned or unpatterned. In one embodiment, the first layer is an organic active layer in an electronic device.

The first layer can be formed by any deposition technique, including vapor deposition techniques, liquid deposition techniques, and thermal transfer techniques. In one embodiment, the first layer is deposited by a liquid deposition technique, followed by drying. In some embodiments, a first material is dissolved or dispersed in a liquid medium. The liquid deposition method may be continuous or discontinuous. Continuous liquid deposition techniques, include but are not limited to, spin coating, roll coating, curtain coating, dip coating, slot-die coating, spray coating, and continuous nozzle coating. Discontinuous liquid deposition techniques include, but are not limited to, ink jet printing, gravure printing, flexographic printing and screen printing. In one embodiment, the first layer is deposited by a continuous liquid deposition technique. The drying step can take place at room temperature or at elevated temperatures, so long as the first material and any underlying materials are not damaged.

The intermediate layer is formed over and in direct contact with the first layer. In some embodiments, substantially all of the first layer is covered by the intermediate layer. In some embodiments, the edges and areas outside the active area of interest are left uncovered. The intermediate layer can be formed by any deposition technique, including vapor deposition techniques, liquid deposition techniques, and thermal transfer techniques.

In one embodiment, the intermediate layer is formed by a vapor deposition process, which can by chemical or physical.

In one embodiment, the intermediate layer is deposited by a liquid deposition technique.

In some embodiments, an intermediate material is dissolved or dispersed in a liquid medium. The liquid deposition method may be continuous or discontinuous, as discussed above. The choice of liquid medium for depositing the intermediate material will depend on the exact nature of the material itself. In one embodiment, the intermediate material is a fluorinated material and the liquid medium is a fluorinated liquid. Examples of fluorinated liquids include, but are not limited to, perfluorooctane, trifluorotoluene, and hexafluoroxylene. After deposition of the liquid composition, the material is dried to form a layer, as discussed above with respect to the first layer.

In some embodiments, the intermediate layer is formed by liquid deposition, but without adding it to a liquid medium. In one embodiment, the intermediate material is a liquid at room temperature and is applied by liquid deposition over the first layer. The liquid intermediate material may be film-forming or it may be absorbed or adsorbed onto the surface of the first layer. In one embodiment, the liquid intermediate material is cooled to a temperature below its melting point in order to form the intermediate layer over the first layer. In one embodiment, the intermediate material is not a liquid at room temperature and is heated to a temperature above its melting point, deposited on the first layer, and cooled to room temperature to form the intermediate layer over the first layer. For the liquid deposition, any of the methods described above may be used.

The thickness of the intermediate layer can depend upon the ultimate end use of the material. In some embodiments, the intermediate layer is at least 100 Å in thickness. In some embodiments, the intermediate layer is in the range of 100-3000 Å; in some embodiments 1000-2000 Å.

The intermediate layer is then treated to remove selected portions to form a pattern of intermediate material over the first layer.

In one embodiment, selected portions of the intermediate layer are removed using photoresist technology. The use of photoresist technology is well known in the art. A photosensitive material, the photoresist, is deposited over the entire surface of the intermediate layer. The photoresist is exposed to activating radiation patternwise. The photoresist is then developed to remove either the exposed or unexposed portions. In some embodiments, development is carried out by treatment with a solvent to remove areas of the photoresist which are more soluble, swellable or dispersible. When areas of the photoresist are removed, this results areas of the intermediate layer which are uncovered. These areas of the intermediate layer are then removed by a controlled etching step. In some embodiments, the etching can be accomplished by using a solvent which will remove the intermediate layer but not the underlying first layer. In some embodiments, the etching can be accomplished by treatment with a plasma. The remaining photoresist is then removed, usually by treatment with a solvent.

In one embodiment, selected portions of the intermediate layer are removed by patternwise treatment with radiation. The terms “radiating” and “radiation” are intended to mean the addition of energy in any form, including heat in any form, the entire electromagnetic spectrum, or subatomic particles, regardless of whether such radiation is in the form of rays, waves, or particles. In one embodiment, the intermediate layer comprises a thermally fugitive material and portions are removed by treatment with an infrared radiation. In some embodiments, the infrared radiation is applied by a laser. Infrared diode lasers are well known and can be used to expose the intermediate layer in a pattern. In one embodiment, portions of the intermediate layer can be removed by exposure to UV radiation.

In one embodiment, selected portions of the intermediate layer are removed by laser ablation. In one embodiment, an excimer laser is used.

In one embodiment, selected portions of the intermediate layer are removed by dry etching. As used herein, the term “dry etching” means etching that is performed using gas(es). The dry etching may be performed using ionized gas(es) or without using ionized gas(es). In one embodiment, at least one oxygen-containing gas is in the gas used. Exemplary oxygen-containing gases include O₂, COF₂, CO, O₃, NO, N₂O, and mixtures thereof. At least one halogen-containing gas may also be used in combination with at least one oxygen-containing gas. The halogen-containing gas can include any one or more of a fluorine-containing gas, a chlorine-containing gas, a bromine-containing gas, or an iodine-containing gas and mixtures thereof.

The second layer is then applied over the uncovered areas of the first layer. The second layer can be applied by any deposition technique. In one embodiment, the second layer is applied by a liquid deposition technique. In some embodiments, a liquid composition comprising a second material dissolved or dispersed in a liquid medium is applied over the patterned intermediate layer, and dried to form the second layer. The liquid composition is chosen to have a surface energy that is greater than the surface energy of the intermediate layer, but approximately the same as or less than the surface energy of the first layer. The liquid composition will wet the first layer, but will be repelled from the intermediate layer. The liquid may spread onto the area of the intermediate layer, but it will de-wet. Thus, a contained second layer is formed.

In one embodiment, the second layer is applied using a continuous liquid deposition technique. In one embodiment, the second layer is applied using a discontinuous liquid deposition technique.

In one embodiment, the first layer is applied over a liquid containment structure. It may be desired to use a structure that is inadequate for complete containment, but that still allows adjustment of thickness uniformity of the printed layer. In this case it may be desirable to control wetting onto the thickness-tuning structure, providing both containment and uniformity. It is then desirable to be able to modulate the contact angle of the emissive ink. Most surface treatments used for containment (e.g., CF4 plasma) do not provide this level of control.

In one embodiment, the first layer is applied over a so-called bank structure. Bank structures are typically formed from photoresists, organic materials (e.g., polyimides), or inorganic materials (oxides, nitrides, and the like). Bank structures may be used for containing the first layer in its liquid form, preventing color mixing; and/or for improving the thickness uniformity of the first layer as it is dried from its liquid form; and/or for protecting underlying features from contact by the liquid. Such underlying features can include conductive traces, gaps between conductive traces, thin film transistors, electrodes, and the like.

In one embodiment of the process provided herein, the first and second layers are organic active layers. The first organic active layer is formed over a first electrode, the first organic active layer is treated with a reactive surface-active composition to reduce the surface energy of the layer, and the second organic active layer is formed over the treated first organic active layer.

In one embodiment, the first organic active layer is formed by liquid deposition of a liquid composition comprising the first organic active material and a liquid medium. The liquid composition is deposited over the first electrode, and then dried to form a layer. In one embodiment, the first organic active layer is formed by a continuous liquid deposition method. Such methods may result in higher yields and lower equipment costs.

In one embodiment, the intermediate layer is formed from a liquid composition. The liquid deposition method can be continuous or discontinuous, as described above. In one embodiment, the intermediate layer liquid composition is deposited using a continuous liquid deposition method.

### 4. Organic Electronic Device

The process will be further described in terms of its application in an electronic device, although it is not limited to such application.

FIG. 2 is an exemplary electronic device, an organic light-emitting diode (OLED) display that includes at least two organic active layers positioned between two electrical contact layers. The electronic device 100 includes one or more layers 120 and 130 to facilitate the injection of holes from the anode layer 110 into the photoactive layer 140. In general, when two layers are present, the layer 120 adjacent the anode is called the hole injection layer or buffer layer. The layer 130 adjacent to the photoactive layer is called the hole transport layer. An optional electron transport layer 150 is located between the photoactive layer 140 and a cathode layer 160. Depending on the application of the device 100, the photoactive layer 140 can be a light-emitting layer that is activated by an applied voltage (such as in a light-emitting diode or light-emitting electrochemical cell), a layer of material that responds to radiant energy and generates a signal with or without an applied bias voltage (such as in a photodetector). The device is not limited with respect to system, driving method, and utility mode.

For multicolor devices, the photoactive layer 140 is made up different areas of at least three different colors. The areas of different color can be formed by printing the separate colored areas. Alternatively, it can be accomplished by forming an overall layer and doping different areas of the layer with emissive materials with different colors. Such a process has been described in, for example, published U.S. patent application 2004-0094768.

In some embodiments, the new process described herein can be used to apply an organic layer (second layer) to an electrode layer (first layer). In one embodiment, the first layer is the anode 110, and the second layer is the buffer layer 120.

In some embodiments, the new process described herein is used for any successive pairs of organic layers in the device, where the second layer is to be contained in a specific area. In one embodiment of the new process, the second organic active layer is the photoactive layer 140, and the first organic active layer is the device layer applied just before layer 140. In many cases the device is constructed beginning with the anode layer. When the hole transport layer 130 is present, the intermediate layer is applied to layer 130 prior to applying the photoactive layer 140. When layer 130 is not present, the intermediate layer is applied to layer 120. In the case where the device is constructed beginning with the cathode, the intermediate layer is applied to the electron transport layer 150 prior to applying the photoactive layer 140.

In one embodiment of the new process, the second organic active layer is the hole transport layer 130, and the first organic active layer is the device layer applied just before layer 130. In the embodiment where the device is constructed beginning with the anode layer, the RSA treatment would be applied to buffer layer 120 prior to applying the hole transport layer 130.

In one embodiment, the anode 110 is formed in a pattern of parallel stripes. The buffer layer 120 and, optionally, the hole transport layer 130 are formed as continuous layers over the anode 110. The intermediate layer is applied as a separate layer directly over layer 130 (when present) or layer 120 (when layer 130 is not present). The intermediate layer is removed in a pattern such that at least the areas between the anode stripes are uncovered. In some embodiments, the areas between the anode stripes and the outer edges of the anode stripes are uncovered.

The layers in the device can be made of any materials which are known to be useful in such layers. The device may include a support or substrate (not shown) that can be adjacent to the anode layer 110 or the cathode layer 150. Most frequently, the support is adjacent the anode layer 110. The support can be flexible or rigid, organic or inorganic. Generally, glass or flexible organic films are used as a support. The anode layer 110 is an electrode that is more efficient for injecting holes compared to the cathode layer 160. The anode can include materials containing a metal, mixed metal, alloy, metal oxide or mixed oxide. Suitable materials include the mixed oxides of the Group 2 elements (i.e., Be, Mg, Ca, Sr, Ba, Ra), the Group 11 elements, the elements in Groups 4, 5, and 6, and the Group 8-10 transition elements. If the anode layer 110 is to be light transmitting, mixed oxides of Groups 12, 13 and 14 elements, such as indium-tin-oxide, may be used. As used herein, the phrase “mixed oxide” refers to oxides having two or more different cations selected from the Group 2 elements or the Groups 12, 13, or 14 elements. Some non-limiting, specific examples of materials for anode layer 110 include, but are not limited to, indium-tin-oxide (“ITO”), aluminum-tin-oxide, gold, silver, copper, and nickel. The anode may also comprise an organic material such as polyaniline, polythiophene, or polypyrrole.

The anode layer 110 may be formed by a chemical or physical vapor deposition process or spin-cast process. Chemical vapor deposition may be performed as a plasma-enhanced chemical vapor deposition (“PECVD”) or metal organic chemical vapor deposition (“MOCVD”). Physical vapor deposition can include all forms of sputtering, including ion beam sputtering, as well as e-beam evaporation and resistance evaporation. Specific forms of physical vapor deposition include rf magnetron sputtering and inductively-coupled plasma physical vapor deposition (“IMP-PVD”). These deposition techniques are well known within the semiconductor fabrication arts.

Usually, the anode layer 110 is patterned during a lithographic operation. The pattern may vary as desired. The layers can be formed in a pattern by, for example, positioning a patterned mask or resist on the first flexible composite barrier structure prior to applying the first electrical contact layer material. Alternatively, the layers can be applied as an overall layer (also called blanket deposit) and subsequently patterned using, for example, a patterned resist layer and wet chemical or dry etching techniques. Other processes for patterning that are well known in the art can also be used. When the electronic devices are located within an array, the anode layer 110 typically is formed into substantially parallel strips having lengths that extend in substantially the same direction.

The buffer layer 120 functions to facilitate injection of holes into the photoactive layer and to smoothen the anode surface to prevent shorts in the device. The buffer layer is typically formed with polymeric materials, such as polyaniline (PANI) or polyethylenedioxythiophene (PEDOT), which are often doped with protonic acids. The protonic acids can be, for example, poly(styrenesulfonic acid), poly(2-acrylamido-2-methyl-1-propanesulfonic acid), and the like. The buffer layer 120 can comprise charge transfer compounds, and the like, such as copper phthalocyanine and the tetrathiafulvalene-tetracyanoquinodimethane system (TTF-TCNQ). In one embodiment, the buffer layer 120 is made from a dispersion of a conducting polymer and a colloid-forming polymeric acid. Such materials have been described in, for example, published U.S. patent applications 2004-0102577 and 2004-0127637.

The buffer layer 120 can be applied by any deposition technique. In one embodiment, the buffer layer is applied by a solution deposition method, as described above. In one embodiment, the buffer layer is applied by a continuous solution deposition method.

Examples of hole transport materials for optional layer 130 have been summarized for example, in Kirk-Othmer Encyclopedia of Chemical Technology, Fourth Edition, Vol. 18, p. 837-860, 1996, by Y. Wang. Both hole transporting molecules and polymers can be used. Commonly used hole transporting molecules include, but are not limited to: 4,4′,4″-tris(N,N-diphenyl-amino)-triphenylamine (TDATA); 4,4′,4″-tris(N-3-methylphenyl-N-phenyl-amino)-triphenylamine (MTDATA); N,N′-diphenyl-N,N′-bis(3-methylphenyl)-[1,1′-biphenyl]-4,4′-diamine (TPD); 1,1-bis[(di-4-tolylamino) phenyl]cyclohexane (TAPC); N,N′-bis(4-methylphenyl)-N,N′-bis(4-ethylphenyl)-[1,1′-(3,3′-dimethyl)biphenyl]-4,4′-diamine (ETPD); tetrakis-(3-methylphenyl)-N,N,N′,N′-2,5-phenylenediamine (PDA); α-phenyl-4-N,N-diphenylaminostyrene (TPS); p-(diethylamino)benzaldehyde diphenylhydrazone (DEH); triphenylamine (TPA); bis[4-(N,N-diethylamino)-2-methylphenyl](4-methylphenyl)methane (MPMP); 1-phenyl-3-[p-(diethylamino)styryl]-5-[p-(diethylamino)phenyl]pyrazoline (PPR or DEASP); 1,2-trans-bis(9H-carbazol-9-yl)cyclobutane (DCZB); N,N,N′,N′-tetrakis(4-methylphenyl)-(1,1′-biphenyl)-4,4′-diamine (TTB); N,N′-bis(naphthalen-1-yl)-N,N′-bis-(phenyl)benzidine (α-NPB); and porphyrinic compounds, such as copper phthalocyanine. Commonly used hole transporting polymers include, but are not limited to, polyvinylcarbazole, (phenylmethyl)polysilane, poly(dioxythiophenes), polyanilines, and polypyrroles. It is also possible to obtain hole transporting polymers by doping hole transporting molecules such as those mentioned above into polymers such as polystyrene and polycarbonate. In some embodiments, the hole transport material comprises a cross-linkable oligomeric or polymeric material. After the formation of the hole transport layer, the material is treated with radiation to effect cross-linking. In some embodiments, the radiation is thermal radiation.

The hole transport layer 130 can be applied by any deposition technique. In one embodiment, the hole transport layer is applied by a solution deposition method, as described above. In one embodiment, the hole transport layer is applied by a continuous solution deposition method.

Any organic electroluminescent (“EL”) material can be used in the photoactive layer 140, including, but not limited to, small molecule organic fluorescent compounds, fluorescent and phosphorescent metal complexes, conjugated polymers, and mixtures thereof. Examples of fluorescent compounds include, but are not limited to, pyrene, perylene, rubrene, coumarin, derivatives thereof, and mixtures thereof. Examples of metal complexes include, but are not limited to, metal chelated oxinoid compounds, such as tris(8-hydroxyquinolato)aluminum (Alq3); cyclometalated iridium and platinum electroluminescent compounds, such as complexes of iridium with phenylpyridine, phenylquinoline, or phenylpyrimidine ligands as disclosed in Petrov et al., U.S. Pat. No. 6,670,645 and Published PCT Applications WO 03/063555 and WO 2004/016710, and organometallic complexes described in, for example, Published PCT Applications WO 03/008424, WO 03/091688, and WO 03/040257, and mixtures thereof. Electroluminescent emissive layers comprising a charge carrying host material and a metal complex have been described by Thompson et al., in U.S. Pat. No. 6,303,238, and by Burrows and Thompson in published PCT applications WO 00/70655 and WO 01/41512. Examples of conjugated polymers include, but are not limited to poly(phenylenevinylenes), polyfluorenes, poly(spirobifluorenes), polythiophenes, poly(p-phenylenes), copolymers thereof, and mixtures thereof.

The photoactive layer 140 can be applied by any deposition technique. In one embodiment, the photoactive layer is applied by a solution deposition method, as described above. In one embodiment, the photoactive layer is applied by a continuous solution deposition method.

Optional layer 150 can function both to facilitate electron injection/transport, and can also serve as a confinement layer to prevent quenching reactions at layer interfaces. More specifically, layer 150 may promote electron mobility and reduce the likelihood of a quenching reaction if layers 140 and 160 would otherwise be in direct contact. Examples of materials for optional layer 150 include, but are not limited to, metal-chelated oxinoid compounds (e.g., Alq₃ or the like); phenanthroline-based compounds (e.g., 2,9-dimethyl-4,7-diphenyl-1,10-phenanthroline (“DDPA”), 4,7-diphenyl-1,10-phenanthroline (“DPA”), or the like); azole compounds (e.g., 2-(4-biphenylyl)-5-(4-t-butylphenyl)-1,3,4-oxadiazole (“PBD” or the like), 3-(4-biphenylyl)-4-phenyl-5-(4-t-butylphenyl)-1,2,4-triazole (“TAZ” or the like); other similar compounds; or any one or more combinations thereof. Alternatively, optional layer 150 may be inorganic and comprise BaO, LiF, Li₂O, or the like.

The cathode 160, is an electrode that is particularly efficient for injecting electrons or negative charge carriers. The cathode layer 160 can be any metal or nonmetal having a lower work function than the first electrical contact layer (in this case, the anode layer 110). In one embodiment, the term “lower work function” is intended to mean a material having a work function no greater than about 4.4 eV. In one embodiment, “higher work function” is intended to mean a material having a work function of at least approximately 4.4 eV.

Materials for the cathode layer can be selected from alkali metals of Group 1 (e.g., Li, Na, K, Rb, Cs,), the Group 2 metals (e.g., Mg, Ca, Ba, or the like), the Group 12 metals, the lanthanides (e.g., Ce, Sm, Eu, or the like), and the actinides (e.g., Th, U, or the like). Materials such as aluminum, indium, yttrium, and combinations thereof, may also be used. Specific non-limiting examples of materials for the cathode layer 160 include, but are not limited to, barium, lithium, cerium, cesium, europium, rubidium, yttrium, magnesium, samarium, and alloys and combinations thereof.

The cathode layer 160 is usually formed by a chemical or physical vapor deposition process.

In other embodiments, additional layer(s) may be present within organic electronic devices.

When the device is made starting with the anode side, the intermediate layer of the new process described herein may be deposited after the formation of the anode 110, after the formation of the buffer layer 120, after the hole transport layer 130, or any combination thereof. When the device is made starting with the cathode side, the intermediate layer of the new process described herein, may be deposited after the formation of the cathode 160, the electron transport layer 150, or any combination thereof.

The different layers may have any suitable thickness. Inorganic anode layer 110 is usually no greater than approximately 500 nm, for example, approximately 10-200 nm; buffer layer 120, and hole transport layer 130 are each usually no greater than approximately 250 nm, for example, approximately 50-200 nm; photoactive layer 140, is usually no greater than approximately 1000 nm, for example, approximately 50-80 nm; optional layer 150 is usually no greater than approximately 100 nm, for example, approximately 20-80 nm; and cathode layer 160 is usually no greater than approximately 100 nm, for example, approximately 1-50 nm. If the anode layer 110 or the cathode layer 160 needs to transmit at least some light, the thickness of such layer may not exceed approximately 100 nm.

### EXAMPLES

The concepts described herein will be further described in the following examples, which do not limit the scope of the invention described in the claims.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges include each and every value within that range.

What is claimed is:

1. A process for forming a contained second layer over a first layer, said process comprising:
forming the first layer having a first surface energy;
forming an intermediate layer over and in direct contact with the first layer, said intermediate layer having a second surface energy which is lower than the first surface energy;
removing selected portions of the intermediate layer to form a pattern comprising uncovered areas of the first layer and covered areas of the first layer; and
forming a contained second layer over the uncovered areas of the first layer.

2. The process of claim 1, wherein the intermediate layer comprises a fluorinated material.

3. The process of claim 1, wherein the intermediate layer is formed in a pattern over the first layer.

4. The process of claim 1 wherein the intermediate layer is formed unpatterned over the first layer.

5. The process of claim 1, wherein the selected portions of the intermediate layer are removed by patternwise treatment with radiation.

6. The process of claim 5, wherein the radiation is infrared radiation.

7. The process of claim 1, wherein the first layer is an organic or inorganic substrate.

8. The process of claim 1, wherein the first layer is an electrode.

9. The process of claim 1, wherein the first layer is an organic active layer.

10. The process of claim 2, wherein the fluorinated material is a fluorinated acid.

11. The process of claim 10, wherein the fluorinated acid is an oligomer.

12. The process of claim 11, wherein the oligomeric fluorinated acid has a fluorinated olefin backbone with fluorinated pendent groups selected from ether sulfonates, ester sulfonates, and ether sulfonimides.

13. A process for making an organic electronic device comprising a first organic active layer and a second organic active layer positioned over an electrode, said process comprising
forming the first organic active layer having a first surface energy over the electrode
forming an intermediate layer over and in direct contact with the first layer, said intermediate layer having a second surface energy which is lower than the first surface energy;
removing selected portions of the intermediate layer to form a pattern comprising uncovered areas of the first layer and covered areas of the first layer; and
forming a contained second layer over the uncovered areas of the first layer.

14. The process of claim 13, wherein the intermediate layer comprises a fluorinated material.

15. The process of claim 13, wherein the intermediate layer is patterned or unpatterned.

16. The process of claim 13, wherein the selected portions of the intermediate layer are removed by patternwise treatment with radiation.

17. The process of claim 14, wherein the fluorinated material is an oligomeric fluorinated acid having a fluorinated olefin backbone with fluorinated pendent groups selected from ether sulfonates, ester sulfonates, and ether sulfonimides.

18. The process of claim 13, wherein the intermediate layer forms at least one liquid containment structure.

19. An organic electronic device comprising a first organic active layer and a second organic active layer positioned over an electrode, and further comprising a patterned intermediate layer between the first organic active layer and the second organic active layer.
